(19) United States
(12) Patent Application Publication
(10) Pub. No.: US 2025/0221225 A1
(43) Pub. Date: Jul. 3, 2025

(54) ORGANIC LIGHT-EMITTING DISPLAY DEVICE

(71) Applicant: LG Display Co., Ltd., Seoul (KR)

(72) Inventors: Min Ki KIM, Paju-si (KR); Hye Min HWANG, Paju-si (KR); Jae Hwan MYUNG, Paju-si (KR)

(73) Assignee: LG Display Co., Ltd., Seoul (KR)

(21) Appl. No.: 18/893,526

(22) Filed: Sep. 23, 2024

(30) Foreign Application Priority Data
Dec. 28, 2023 (KR) 10-2023-0194691

(51) Int. Cl. H10K 59/38; H10K 59/80

(52) U.S. Cl. CPC H10K 59/38; H10K 59/873

(57) ABSTRACT

Discussed is an organic light-emitting display device including a substrate that includes a plurality of pixel regions, a light-emitting element formed in each of the plurality of pixel regions of the substrate, a color filter layer including red, green, and blue color filters located on the light-emitting elements to correspond to each of the plurality of pixel regions, and a color purifier layer located between the light-emitting element and the color filter layer and including at least two metal layers and at least one dielectric layer.

### CROSS-REFERENCE TO RELATED APPLICATION

This application claims priority to Korean Patent Application No. 10-2023-0194691, filed in the Republic of Korea on Dec. 28, 2023, the entire contents of which is hereby expressly incorporated by reference into the present application.

### BACKGROUND

### 1. Field

The present disclosure relates to a display device, and more specifically, to an organic light-emitting display device (OLED).

### 2. Discussion of the Related Art

Nowadays, there has been an increase in interest in information displays which process and display large amounts of information and there is greater demand for using portable information media to obtain such information. Accordingly, the display field has rapidly developed to try to accommodate such increased demand, and in response to this increase, various lightweight and thin flat plate display devices have been developed and are receiving attention for additional development.

Specific examples of the thin flat plate display devices include liquid crystal display devices (LCD), plasma display panel devices (PDP), field emission display devices (FED), electroluminescence display devices (ELD), organic light-emitting display devices (OLED), and the like, and the thin flat plate display devices have come to exhibit excellent performance while being thin, light and consuming low power, and thus are rapidly replacing conventional cathode ray tubes (CRTs).

Among the above thin flat plate display devices, the organic light-emitting display device (hereinafter referred to as OLED) is a self-luminating and does not require use of a backlight unlike that of a liquid crystal display device. By not using the backlight, the OLED can be made much thinner than the liquid crystal display device.

Further, the organic light-emitting display devices have excellent viewing angles and contrast ratios, are advantageous in an aspect of power consumption, can be driven at a low direct current voltage, and have fast response time compared to the liquid crystal display devices. Additionally, inner components of the organic light-emitting display devices can be more robust, which gives the organic light-emitting display devices advantages of being resistant to external shocks and being able to be used in a wide range of temperatures.

Specifically, since a manufacturing process of the organic light-emitting display devices is simple, there is an advantage in that production costs can be significantly reduced compared to a conventional liquid crystal display device.

Development for the OLED is being actively performed in order to use the OLED as various display devices in a head mounted display (HMD) such as a glasses-type monitor device of virtual reality (VR) or augmented reality worn in the form of glasses or a helmet and having a focus formed at a short distance in front of eyes of users of the HMD.

### SUMMARY OF THE DISCLOSURE

The present disclosure is directed to providing an organic light-emitting display device which allows light emitted from light-emitting elements to realize a high color gamut (or a high level of a color reproduction rate) while realizing each of red (R), green (G), and blue (B) colors while passing through color filters.

The technical problems of the present disclosure are not limited to the above-mentioned technical problems, and other technical problems which are not mentioned will be clearly understood by those skilled in the art from the following description.

A display device according to one embodiment of the present disclosure comprises a substrate where a plurality of pixel regions are defined; a light-emitting element formed in each of the plurality of pixel regions of the substrate; a color filter layer including red, green, and blue color filters located on the light-emitting elements to correspond to each of the plurality of pixel regions; and a color purifier layer located between the light-emitting element and the color filter layer and including at least two metal layers and at least one dielectric layer.

According to the present disclosure, light emitted from the light-emitting elements can realize a high color gamut while realizing each of red, green, and blue colors while passing through a color purifier layer including a metal and a dielectric.

According to the present disclosure, since the color purifier layer can be additionally formed on an electrode of the light-emitting element or used as a cathode, manufacturing costs and manufacturing processes can be reduced.

According to the present disclosure, the color purifier layer can be formed in the encapsulation layer, or formed at the top or bottom of the encapsulation layer, and thus can be replaced with a thin film encapsulation layer.

According to the present disclosure, as the color purifier layer is used, a high color gamut which may not be realized by conventional color filters can be realized.

According to the present disclosure, it is possible to develop a white organic light-emitting display device on silicon (OLEDos) product with a more excellent color gamut than an R/G/B method.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a schematic block diagram of a light-emitting display device;

FIG. 2 is a schematic circuit diagram of a sub-pixel;

FIG. 3 is a view schematically illustrating a planar layout of sub-pixels according to one embodiment of the present disclosure;

FIG. 4 is a cross-sectional view according to a first embodiment of the present disclosure taken along cutting line I-I′ in FIG. 3;

FIG. 5 is an enlarged cross-sectional view illustrating portion ‘A’ in FIG. 4;

FIG. 6 is a view illustrating the progress of light transmitted through metal layers and a dielectric layer constituting a color purifier layer in FIG. 5;

FIG. 7 is a cross-sectional view according to a second embodiment of the present disclosure taken along cutting line I-I′ in FIG. 3;

FIG. 8 is an enlarged cross-sectional view illustrating portion ‘B’ in FIG. 7;

FIG. 9 is a view illustrating the progress of light transmitted through metal layers and dielectric layers constituting a color purifier layer in FIG. 8;

FIG. 10 is a view illustrating the progress of light transmission shown for each of thicknesses of the dielectric layers of the color purifier layers according to the first and second embodiments of the present disclosure;

FIG. 11 is a view illustrating transmittance of the color purifier layers according to the first and second embodiments of the present disclosure;

FIG. 12 is a view illustrating transmittance according to a wavelength range in a visible light region of the metal layers of the color purifier layer of the organic light-emitting display device according to the embodiment of the present disclosure;

FIG. 13 is a view illustrating transmittance according to a wavelength range in an ultraviolet region of the metal layers of the color purifier layer of the organic light-emitting display device according to the embodiment of the present disclosure;

FIG. 14 is a view illustrating a state in which a transmittance peak is shifted by the dielectric layer of the color purifier layer of the organic light-emitting display device according to the embodiment of the present disclosure;

FIG. 15 is a view illustrating transmittance according to a metal material applied to the metal layer of the color purifier layer of the organic light-emitting display device according to the embodiment of the present disclosure;

FIG. 16 is a view illustrating transmittance of the organic light-emitting display devices according to the first and second embodiments of the present disclosure;

FIG. 17 is a view illustrating a color gamut of the organic light-emitting display device according to one embodiment of the present disclosure;

FIGS. 18A to 18H are cross-sectional views of manufacturing processes of the organic light-emitting display device according to one embodiment of the present disclosure; and

FIG. 19 is a cross-sectional view of an organic light-emitting display device according to a third embodiment of the present disclosure.

### DETAILED DESCRIPTION OF THE EMBODIMENTS

Hereinafter, an organic light-emitting display device according to various embodiments of the present disclosure will be described with reference to the accompanying drawings.

In the following description, when it is determined that a detailed description of known functions or configurations related to the present disclosure can unnecessarily obscure the gist of the present disclosure, the detailed description thereof will be omitted or briefly described.

An organic light-emitting display device, a liquid crystal display device, and an electrophoretic display device, or the like can be used as examples of the display device according to the present disclosure, but the organic light-emitting display device is described as the example in the present disclosure. The organic light-emitting display device includes an organic light-emitting layer composed of an organic material between a first electrode which is an anode and a second electrode which is a cathode.

Accordingly, the organic light-emitting display device is a self-luminous display device in which holes supplied from the first electrode and electrons supplied from the second electrode are combined in the organic light-emitting layer to form excitons which are hole-electron pairs, and light is emitted by energy generated when the excitons return to a bottom state.

In the disclosure, the term “can” fully encompasses all the meanings and coverages of the term “may.”

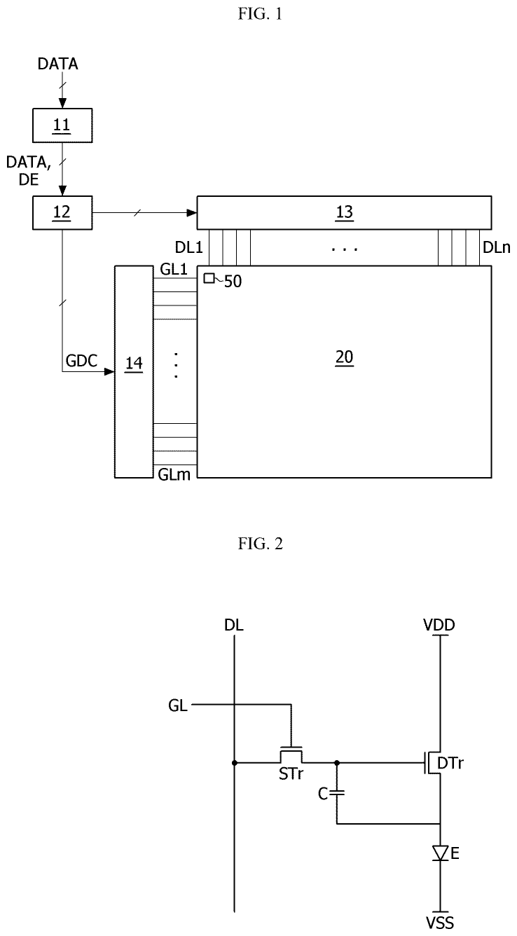

FIG. 1 is a schematic block diagram of the organic light-emitting display device, and FIG. 2 is a schematic circuit diagram of a sub-pixel. All components of each organic light-emitting display device according to all embodiments of the present disclosure are operatively coupled and configured.

As shown in FIG. 1, an organic light-emitting display device 100 includes an image processing unit 11, a timing controller 12, a data driver 13, a scan driver 14, and a display panel 20.

The image processing unit 11 outputs a data enable signal DE in addition to a data signal DATA supplied from the outside. The image processing unit 11 can output one or more among a vertical synchronization signal, a horizontal synchronization signal, and a clock signal in addition to the data enable signal DE, but these signals are omitted for convenience of description.

The timing controller 12 receives the data signal DATA in addition to the data enable signal DE or driving signals including the vertical synchronization signal, the horizontal synchronization signal, the clock signal, and the like from the image processing unit 11.

The timing controller 12 outputs a gate timing control signal GDC for controlling an operation timing of the scan driver 14 and a data timing control signal DDC for controlling an operation timing of the data driver 13 based on the driving signal.

The data driver 13 samples and latches the data signal DATA from the timing controller 12 in response to the data timing control signal DDC supplied from the timing controller 12, converts the data signal DATA into a gamma reference voltage, and outputs the gamma reference voltage. The data driver 13 outputs the data signal DATA through data lines DL1 to DLn. The data driver 13 can be formed in the form of an integrated circuit (IC).

The scan driver 14 outputs a scan signal in response to the gate timing control signal GDC supplied from the timing controller 12. The scan driver 14 outputs the scan signal through gate lines GL1 to GLm. The scan driver 14 is formed in the form of an integrated circuit (IC) or formed in the display panel 20 in a gate in panel (GIP) method.

The display panel 20 displays an image in response to the data signal DATA and the scan signal supplied from the data driver 13 and the scan driver 14. The display panel 20 includes sub-pixels 50 which operates so that the image can be displayed.

The sub-pixels 50 include a red sub-pixel, a green sub-pixel, and a blue sub-pixel, or include a white sub-pixel, a red sub-pixel, a green sub-pixel, and a blue sub-pixel. The sub-pixels 50 can have one or more different emission regions according to light-emitting properties.

As shown in FIG. 2, one sub-pixel includes a switching thin film transistor STr, a driving thin film transistor DTr, a capacitor C, a compensation circuit, and a light-emitting element E which is an organic light-emitting diode.

The switching thin film transistor STr performs a switching operation in response to the scan signal supplied through a gate line GL so that the data signal supplied through a data line DL is stored as a data voltage in the capacitor C. The driving thin film transistor DTr operates so that a driving current flows between a power line VDD (high potential voltage) and a cathode power line VSS (low potential voltage) according to the data voltage stored in the capacitor C. The organic light-emitting element E operates to emit light according to the driving current formed by the driving thin film transistor DTr.

The compensation circuit is a circuit added to the sub-pixel to compensate for a threshold voltage of the driving thin film transistor DTr. The compensation circuit includes one or more transistors.

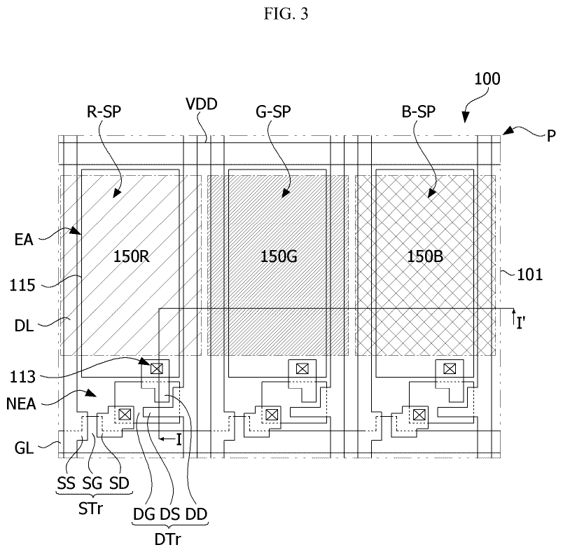

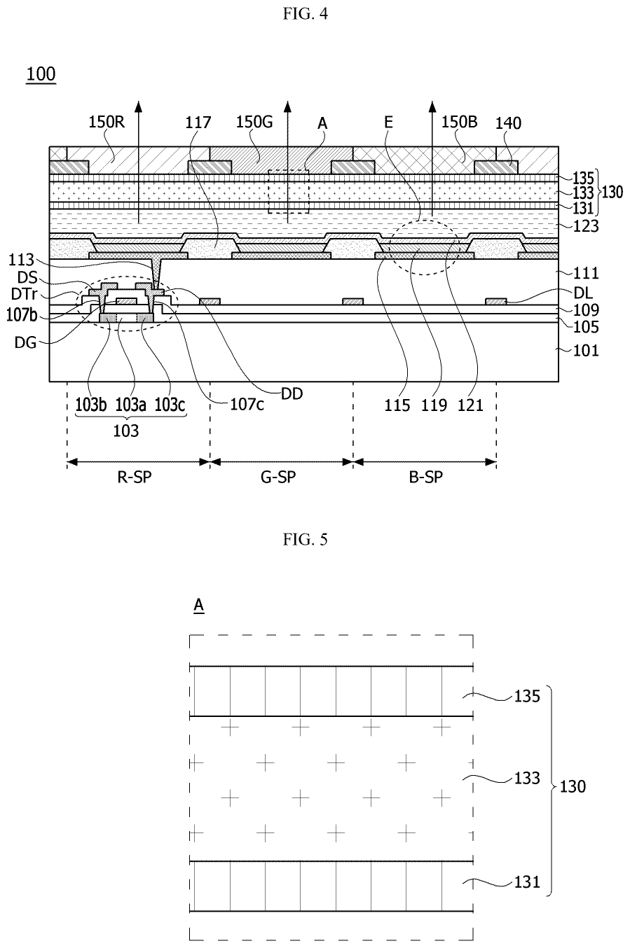

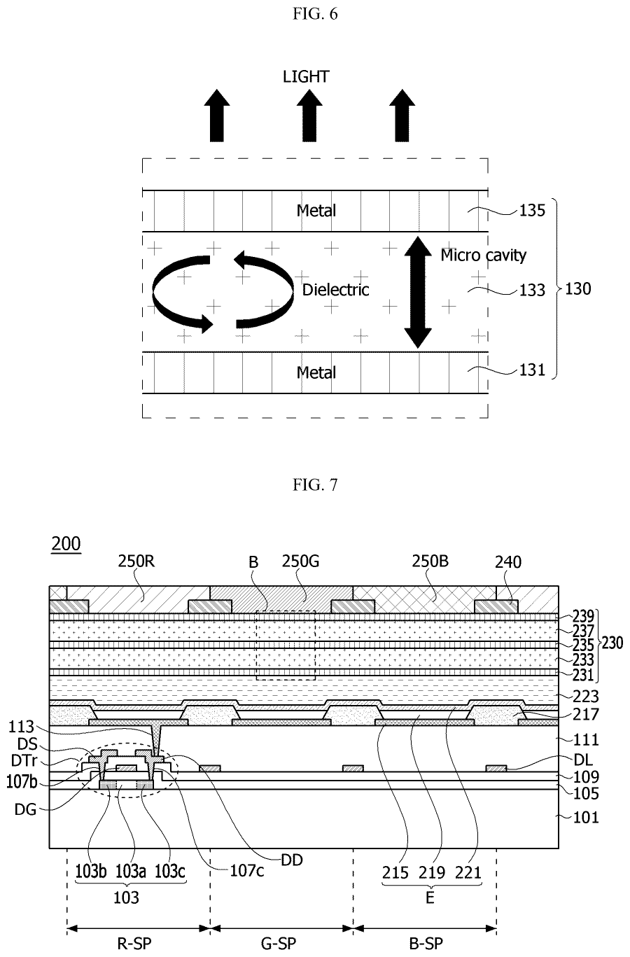

FIG. 3 is a view schematically illustrating a planar layout of the sub-pixels according to one embodiment of the present disclosure. FIG. 4 is a cross-sectional view according to a first embodiment of the present disclosure taken along cutting line I-I′ in FIG. 3. FIG. 5 is an enlarged cross-sectional view illustrating portion ‘A’ in FIG. 4.

The organic light-emitting display device (OLED) 100 according to one embodiment of the present disclosure is divided into a top emission type and a bottom emission type according to transmission directions of the emitted light, and hereinafter the top emission type will be described as an example in the present disclosure.

As shown in FIG. 3, in the organic light-emitting display device (OLED) 100 according to one embodiment of the present disclosure, one unit pixel P can include red, green, and blue sub-pixels R-SP, G-SP, and B-SP, but embodiments of the present disclosure are not limited thereto, and other sub-pixels or other color sub-pixels can be included. Each of the sub-pixels R-SP, G-SP, and B-SP can include an emission region EA, and a non-emission region NEA can be formed along an edge of the emission region EA. The organic light-emitting display device (OLED) 100 can include a plurality of pixels P.

Here, for convenience of description, the sub-pixels R-SP, G-SP, and B-SP are shown to be located in parallel with the same width, but each of the sub-pixels R-SP, G-SP, and B-SP can be configured in various structures with different widths or in different arrangements.

In this case, switching and driving thin film transistors STr and DTr are provided on the non-emission region NEA in each of the sub-pixels R-SP, G-SP, and B-SP, and the light-emitting element E including an anode 115, an organic light-emitting layer (119 in FIG. 4), and a cathode (121 in FIG. 4) is disposed on the emission region EA in each of the sub-pixels R-SP, G-SP, and B-SP.

Here, the switching thin film transistor STr and the driving thin film transistor DTr are connected to each other, and the driving thin film transistor DTr is connected to the light-emitting element E.

In more detail, the gate line GL, the data line DL, and the power line VDD are disposed on a substrate 101 to define each of the sub-pixels R-SP, G-SP, and B-SP.

The switching thin film transistor STr is formed at the intersection of the gate line GL and the data line DL, and the switching thin film transistor STr performs a function of selecting the sub-pixel R-SP, G-SP, or B-SP.

The switching thin film transistor STr includes a gate electrode SG branched from the gate line GL, a semiconductor layer (103 in FIG. 4), a source electrode SS, and a drain electrode SD.

Further, the driving thin film transistor DTr serves to drive the light-emitting element E of the sub-pixel R-SP, G-SP, or B-SP selected by the switching thin film transistor STr. This driving thin film transistor DTr includes a gate electrode DG connected to the drain electrode SD of the switching thin film transistor STr, the semiconductor layer 103, a source electrode DS connected to the power line VDD, and a drain electrode DD.

The drain electrode DD of the driving thin film transistor DTr is connected to the anode 115 of the light-emitting element E.

The organic light-emitting layer 119 is interposed between the anode 115 and the cathode 121.

The organic light-emitting display device 100 according to the first embodiment of the present disclosure will be described in more detail with reference to FIGS. 4 and 5.

Referring to FIG. 4, the semiconductor layer 103 is located on a switching region of each of the sub-pixels R-SP, G-SP, and B-SP on the substrate 101. The semiconductor layer 103 is made of silicon, and includes an active region 103a forming a channel at a central portion thereof, and source and drain regions 103b and 103c doped with a high concentration of impurities at both side surfaces of the active region 103a.

A gate insulating film 105 is disposed on the semiconductor layer 103.

The gate electrode DG and the gate line GL are disposed in one direction on the gate insulating film 105 to correspond to the active region 103a of the semiconductor layer 103.

A first interlayer insulating film 109 is disposed on the gate insulating film 105 including the gate electrode DG and the gate line GL. The first interlayer insulating film 109 and the gate insulating film 105 under the first interlayer insulating film 109 include first and second semiconductor layer contact holes 107b and 107c which respectively expose the source and drain regions 103b and 103c located at both side surfaces of the active region 103a.

The first interlayer insulating film 109 can be formed of an inorganic insulating material such as silicon oxide (SiOₓ) or silicon nitride (SiNₓ), or an organic insulating material such as photo acryl or benzocyclobutene to planarize the substrate 101.

The source and drain electrodes DS and DD which are spaced apart from each other and respectively in contact with the source and drain regions 103b and 103c exposed through the first and second semiconductor layer contact holes 107b and 107c are provided on the first interlayer insulating film 109 including the first and second semiconductor layer contact holes 107b and 107c.

The source and drain electrodes DS and DD, the semiconductor layer 103 including the source and drain regions 103b and 103c in contact with these electrodes DS and DD, the gate insulating film 105 located on the semiconductor layer 103, and the gate electrode DG form the driving thin film transistor DTr.

Meanwhile, the switching thin film transistor STr can have the same structure as the driving thin film transistor DTr and can be connected to the driving thin film transistor DTr.

Further, in the drawing, the switching thin film transistor STr and the driving thin film transistor DTr are exemplified in a top gate type in which the semiconductor layer 103 includes a polysilicon semiconductor layer or an oxide semiconductor layer, and can be provided as a bottom gate type composed of pure and impure amorphous silicon as a modified example thereof.

The switching thin film transistor STr can be further formed in each of the sub-pixels R-SP, G-SP, and B-SP on the substrate 101. In this case, the gate electrode DG of the driving thin film transistor DTr is connected to a drain electrode of the switching thin film transistor STr, and the source electrode SS of the driving thin film transistor DTr is connected to a power line. Further, a gate electrode and a source electrode of the switching thin film transistor STr can be respectively connected to the gate line and the data line, but are not limited thereto.

In addition, one or more sensing thin film transistors with the same structure as the driving thin film transistor DTr can be further formed in each of the sub-pixels R-SP, G-SP, and B-SP on the substrate 101.

When the semiconductor layer 103 includes an oxide semiconductor layer, a light-shielding layer can be further located under the semiconductor layer 103, and a buffer layer can be located between the light-shielding layer and the semiconductor layer 103.

Further, a second interlayer insulating film 111 can be disposed on the source and drain electrodes DS and DD and the first interlayer insulating film 109 exposed between the two electrodes DS and DD.

The second interlayer insulating film 111 can be formed of an inorganic insulating material such as silicon oxide (SiOₓ) or silicon nitride (SiNₓ), or formed of an organic insulating material such as photo acryl or benzocyclobutene to planarize the substrate 101. But, embodiments of the present disclosure are not limited thereto.

Meanwhile, an insulating film composed of an inorganic insulating material such as silicon oxide (SiOₓ) or silicon nitride (SiNₓ) can be further formed between the second interlayer insulating film 111 and the source and drain electrodes DS and DD.

A first electrode 115 can be formed of a conductive material with a relatively high work function in each of the sub-pixels R-SP, G-SP, and B-SP on the second interlayer insulating film 111. The first electrode 115 in each of the sub-pixels R-SP, G-SP, and B-SP is connected to the drain electrode DD of the driving thin film transistor DTr through a drain contact hole 113, and for example, an anode of the light-emitting element E includes a transparent material with a relatively high work function value, but is not limited thereto.

The first electrode 115 is located for each of the sub-pixels R-SP, G-SP, and B-SP.

The first electrode 115 can include at least one stacked structure or at least one selected from the group including indium tin oxide (ITO), indium zinc oxide (IZO), zinc oxide (ZnO), indium oxide (In₂O₃), indium gallium oxide (IGO), and aluminum zinc oxide (AZO). However, the present disclosure is not limited thereto.

Meanwhile, the organic light-emitting display device according to the first embodiment of the present disclosure can be a top emission type in which light from the light-emitting element E is output in an opposite direction to the substrate 101. Accordingly, the first electrode 115 can further include a reflective electrode or reflective layer formed of a metal material with high reflectivity under a transparent conductive material. For example, the reflective electrode or reflective layer can include an aluminum-palladium-copper (APC) alloy or silver (Ag), but is not limited thereto. In this case, the first electrode 115 can have a triple-layer structure of ITO/APC/ITO or ITO/Ag/ITO, but is not limited thereto.

A bank 117 is formed of an insulating material on the first electrode 115. The bank 117 overlaps and covers an edge of the first electrode 115 and exposes a central portion of the first electrode 115. This bank 117 can be formed of an inorganic insulating material. For example, the bank 117 can be formed of silicon oxide (SiO₂) or silicon nitride (SiNₓ), but is not limited thereto.

On the other hand, the bank 117 can be formed of an organic insulating material, but is not limited thereto.

The organic insulating material can include one or more among photoresist, polyacrylates resin, epoxy resin, phenolic resin, polyamides resin, polyimides resin, unsaturated polyesters resin, polyphenylene ether resin, polyphenylene sulfide resin, and benzocyclobutene.

The light-emitting layer 119 is formed on the first electrode 115 exposed through the bank 117. The light-emitting layer 119 can emit white light.

The light-emitting layer 119 can include a first charge auxiliary layer, a light-emitting material layer, and a second charge auxiliary layer sequentially located from an upper portion of the first electrode 115. The light-emitting material layer can have a single-layer or multi-layer structure including at least one of red, green, and blue light-emitting materials, but is not limited thereto. When the light-emitting material layer has a multi-layer structure, a charge generation layer (charge or first or second charge auxiliary layer) can be further formed between the light-emitting material layers. Here, the light-emitting material can be an organic light-emitting material such as a phosphorescent compound or fluorescent compound, or an inorganic light-emitting material such as a quantum dot.

The first charge auxiliary layer can be a hole auxiliary layer, and the hole auxiliary layer can include at least one of a hole injecting layer (HIL) and a hole transporting layer (HTL). Further, the second charge auxiliary layer can be an electron auxiliary layer, and the electron auxiliary layer can include at least one of an electron injecting layer (EIL) and an electron transporting layer (ETL). However, the present disclosure is not limited thereto.

The light-emitting layer 119 can be formed through a vacuum thermal evaporation process. Here, the light-emitting layer 119 is shown to be formed in the bank 117, but the light-emitting layer 119 can be formed substantially on the entire surface of the substrate 101. For example, the light-emitting layer 119 can also be formed on the bank 117, but is not limited thereto.

Alternatively, the light-emitting layer 119 can be formed through a solution process, and a spin coating method, an inkjet printing method, or a screen printing method can be used as the solution process. But, the present disclosure is not limited thereto.

On the-light-emitting layer 119, a second electrode 121 composed of a conductive material with a relatively low work function can be formed substantially on the entire surface of the substrate 101. Here, the second electrode 121 can be formed of aluminum, magnesium, silver, or an alloy thereof. But, the present disclosure is not limited thereto. In this case, the second electrode 121 has a relatively thin thickness so that light from the light-emitting layer 119 can be transmitted. On the other hand, the second electrode 121 can be formed of a transparent conductive material such as indium-gallium-oxide (IGO). But, the present disclosure is not limited thereto.

The first electrode 115, the light-emitting layer 119, and the second electrode 121 form the light-emitting element E. Here, the first electrode 115 can function as an anode and the second electrode 121 can function as a cathode, but are not limited thereto.

As mentioned above, the organic light-emitting display device 100 according to the first embodiment of the present disclosure can be a top emission type in which light from the light-emitting layer 119 of the light-emitting element E output in the opposite direction to the substrate 101, for example, to the outside through the second electrode 121, but is not limited thereto. The top emission type can have a wider emission region than the bottom emission type of the same area, and thus can improve brightness and lower power consumption.

An encapsulation layer 123 can be formed on the second electrode 121. The encapsulation layer 123 protects the light-emitting element E by blocking moisture or oxygen introduced from the outside. The encapsulation layer 123 can include an ultraviolet hardening sealant (UV sealant) or a frit sealant. On the other hand, the encapsulation layer 123 can have a stacked structure of an inorganic film/an organic film/an inorganic film.

Referring to FIGS. 4 and 5, a color purifier layer 130 including a first metal layer 131, a dielectric layer 133, and a second metal layer 135 can be formed on the encapsulation layer 123.

In this case, the color purifier layer 130 amplifies and emits (or preferentially transmits) light in a specific wavelength range or specific wavelength ranges due to a ripple phenomenon of the dielectric layer 133 and a micro cavity phenomenon of the first and second metal layers 131 and 135. Further, all light in the remaining wavelength ranges is offset and disappears.

The light in the specific wavelength range amplified through the color purifier layer 130 can be emitted through red, green, and blue color filter layers 150R, 150G, and 150B.

The first and second metal layers 131 and 135 can have thicknesses in a range of 10 nm to 100 nm.

It is preferable that the first metal layer 131 and the second metal layer 135 have the same thickness, but the present disclosure is not necessarily limited thereto.

Further, materials of the first and second metal layers 131 and 135 can include Ag or an Ag alloy. Ag alloy materials can contain Ag and at least one of Yb, Mg, Cu, Al, Au, Pb, or the like. Specifically, in present disclosure, an example in which Ag is applied will be described.

Ag exhibits maximum transmittance in a wavelength range of 330 nm and has a property of transmitting light in a certain wavelength range even at a thickness of roughly 1000 Å.

The dielectric layer 133 can include a silicon nitride (SiNₓ) film/inkjet printing type PI, a monomer, or a silicon nitride (SiNₓ) film. But, the present disclosure is not limited thereto. Alternatively, the dielectric layer 133 can include an inorganic material, an organic material, or a combination of the inorganic material and the organic material. But, the present disclosure is not limited thereto. The inorganic material can include a silicon nitride (SiNₓ) film, a silicon oxide (SiOₓ) film, an aluminum oxide (AlOₓ) film, IZO, ZnO, or ITO. But, the present disclosure is not limited thereto. Further, the organic material can further include a monomer, a polymer, polyimide (PI), or other organic materials. But, the present disclosure is not limited thereto.

An overall thickness of the color purifier layer 130 can range from 0.4 μm to 2 μm. But, the present disclosure is not limited thereto. Further, a thickness of the dielectric layer 133 can range from 0.4 μm to 2 μm. But, the present disclosure is not limited thereto.

The dielectric layer 133 can replace a function of an encapsulation layer (thin film encapsulation layer) of the organic light-emitting display device.

Referring to FIG. 4, black matrices 140 can be formed on the color purifier layer to correspond to boundaries of adjacent sub-pixels R-SP, G-SP, and B-SP. The black matrix 140 can include a black resin or a double film of chromium oxide (CrOₓ) and chromium (Cr), but is not limited thereto.

The red, green, and blue color filter layers 150R, 150G, and 150B can be formed on the color purifier layer 130 located between the black matrices 140 and correspond to each of the sub-pixels R-SP, G-SP, and B-SP.

The dielectric layer 133 can replace a function of the encapsulation layer, and the color purifier layer 130 can be formed in contact with the second electrode 121 of the light-emitting element E and the red, green, and blue color filter layers 150R, 150G, and 150B.

With reference to FIG. 4, in various embodiments of the present disclosure, another encapsulation layer can be formed on the second metal layer 135 to be interposed between the second metal layer 135 and the red, green, and blue color filter layers 150R, 150G, and 150B. The another encapsulation layer can perform the same function as the encapsulation layer 123 to protect the light-emitting element E by blocking moisture or oxygen introduced from the outside. Similarly, the another encapsulation layer can include an ultraviolet hardening sealant (UV sealant) or a frit sealant. Also, the another encapsulation layer can have a stacked structure of an inorganic film/an organic film/an inorganic film.

Also, with reference to FIG. 4, each of the first metal layer 131 and the second metal layer 135 can be formed as a sheet that covers or overlaps each of the sub-pixels R-SP, G-SP, and B-SP. For example, the first metal layer 131 and/or the second metal layer 135 can overlap or cover respective emission regions E of the sub-pixels R-SP, G-SP, and B-SP. In this regard, the first metal layer 131 and the second metal layer 135 do not include a hole or an opening in a location that overlap the emission region E or the red, green, and blue color filter layers 150R, 150G, and 150B, of the sub-pixels R-SP, G-SP, and B-SP, respectively, but the present disclosure is not limited thereto.

Also, with reference to FIGS. 4 and 5, each of first and second metal layers 131 and 135 can have thicknesses that are the same within itself, but the present disclosure is not limited there to. For example, thicknesses in each of the first and second metal layers 131 and 135 can vary, where a thickness of a first portion overlapping the emission region E can be different from a thickness of a second portion overlapping the bank 117 or the black matrix 140. Accordingly, the first portion can have a thickness that is equal to, less than, or greater than that of the second portion.

Additionally, with reference to FIGS. 4 and 5, the dielectric layer 133 can have thicknesses that are the same within itself, but the present disclosure is not limited there to. For example, thicknesses in the dielectric layer 133 can vary, where a thickness of a first portion overlapping the emission region E can be different from a thickness of a second portion overlapping the bank 117 or the black matrix 140. Accordingly, the first portion can have a thickness that is equal to, less than, or greater than that of the second portion.

Additionally, with reference to FIG. 4, each component of the color purifier layer 130 including the dielectric layer 133 and the first and second metal layers 131 and 135 are shown coplanar across the respective the sub-pixels R-SP, G-SP, and B-SP, but the present disclosure is not limited thereto. For example, a level of portions of the color purifier layer 130 respectively in the sub-pixels R-SP, G-SP, and B-SP can be the same or different. For example, a level of the color purifier layer 130 in the red sub-pixel R-SP can be different from that of the green and/or blue sub-pixels G-SP and B-SP. For example, the level of the color purifier layer 130 in the red sub-pixel R-SP can be higher than or lower than that of the green and/or blue sub-pixels G-SP and B-SP based on a thickness of the underlying portion of the encapsulation layer 123, and/or a level of the light-emitting element E, including that of the organic light-emitting layer 119. Meanwhile, thicknesses of the respective dielectric layer 133 and the first and second metal layers 131 and 135 can be maintained to provide a ripple phenomenon due to a micro cavity phenomenon within each sub-pixels R-SP, G-SP, and B-SP.

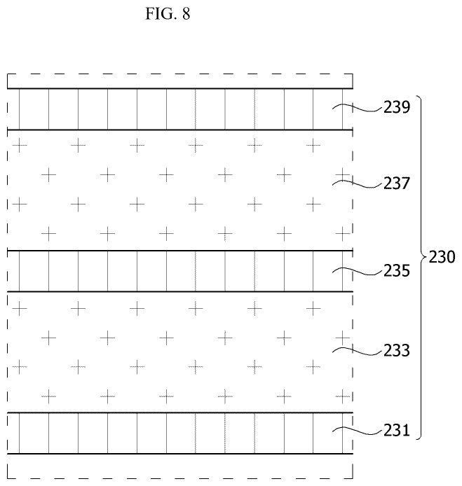

FIG. 6 is a view illustrating the progress of light transmitted through the metal layers and the dielectric layer constituting the color purifier layer in FIG. 5.

Referring to FIG. 6, as light incident from the light-emitting element E on the color purifier layer 130 passes through the dielectric layer 133 with a thickness of at least 500 nm or more, a phenomenon in which transmittance of light fluctuates like a wave due to a ripple phenomenon occurs.

Further, light in a specific wavelength range is amplified through the first and second metal layers 131 and 135 with the dielectric layer 133 of the thickness in which a ripple phenomenon appears therebetween due to a micro cavity phenomenon. Further, the light in the remaining wavelength ranges is offset and disappears.

Here, the micro cavity phenomenon means a phenomenon in which a light-emitting spectrum changes by a mutual light interference effect due to reflectivity of a reflective electrode and transmittance of a translucent electrode and a distance between the two electrodes, for example, the thickness of the dielectric layer.

The second metal layer 135 amplifies light in a specific wavelength range among light in which the ripple phenomenon in which the transmittance fluctuates like a wave through the dielectric layer 133 occurs, and narrowly emits the light.

The narrow light emitted through the second metal layer 135 in this way realizes a high color gamut through the red, green, and blue color filter layers 150R, 150G, and 150B.

Ultimately, light in the specific wavelength range among light emitted from the light-emitting element E is amplified through the color purifier layer 130 including the first metal layer 131, the dielectric layer 133, and the second metal layer 135, and is narrowly emitted through the red, green, and blue color filter layers 150R, 150G, and 150B.

Accordingly, a light source narrowed through the color purifier layer 130 can realize a high color gamut which may not be realized by conventional colors filter while passing through the red, green, and blue color filter layers 150R, 150G, and 150B.

Hereinafter, an organic light-emitting display device according to a second embodiment of the present disclosure will be described.

FIG. 7 is a cross-sectional view according to a second embodiment of the present disclosure taken along cutting line I-I′ in FIG. 3. FIG. 8 is an enlarged cross-sectional view illustrating portion ‘B’ in FIG. 7.

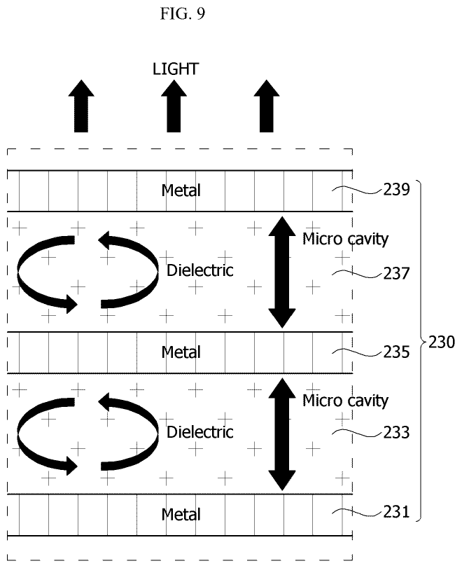

FIG. 9 is a view illustrating the progress of light transmitted through metal layers and dielectric layers constituting a color purifier layer in FIG. 8.

FIG. 7 is a view illustrating an organic light-emitting display device 200 according to the second embodiment of the present disclosure, and has a difference only in the configuration of the color purifier layer from the first embodiment of the present disclosure, and other configurations are the same.

In description of the second embodiment of the present disclosure, description for the same configuration as the first embodiment will be omitted, and the configuration of the color purifier layer which is different from the first embodiment will be described.

Referring to FIGS. 7 and 8, on a substrate 101 where a plurality of pixel regions (or pixels, or sub-pixels) are defined, a light-emitting element E located in each of the plurality of pixel regions of the substrate and including a first electrode 215, a light-emitting layer 219, and a second electrode 221 is formed.

An encapsulation layer 223 is formed on the second electrode 221. The encapsulation layer 223 protects the light-emitting element E by blocking moisture or oxygen introduced from the outside. The encapsulation layer 223 can include an ultraviolet hardening sealant (UV sealant) or a frit sealant. On the other hand, the encapsulation layer 223 can have a stacked structure of an inorganic film/an organic film/an inorganic film.

A color purifier layer 230 including a first metal layer 231, a first dielectric layer 233, a second metal layer 235, a second dielectric layer 237 and a third metal layer 239 is formed on the encapsulation layer 223.

In this case, the color purifier layer 230 amplifies and emits light in a specific wavelength range due to a ripple phenomenon of the first and second dielectric layers 233 and 237 and a micro cavity phenomenon of the first, second, and third metal layers 231, 235, and 239.

The light in the specific wavelength range amplified through the color purifier layer 230 in this way is emitted through red, green, and blue color filter layers 250R, 250G, and 250B.

The first to third metal layers 231, 235, and 239 have thicknesses in a range of 10 nm to 100 nm. The first metal layer 231 and the third metal layer 239 can have the same thickness. However, the present disclosure is not necessarily limited thereto. The thickness of the second metal layer 235 can be roughly 1.5 to 2.5 times the thickness of the first metal layer 231. Preferably, the thickness of the second metal layer 235 can be roughly twice the thickness of the first metal layer 231. Alternatively, the thickness of the second metal layer 235 can be similar to the sum of the thicknesses of the first metal layer 231 and the third metal layer 239.

Further, materials of the first to third metal layers 231, 235, and 239 can include Ag or an Ag alloy. Ag alloy materials can contain Ag and at least one of Yb, Mg, Cu, Al, Au, Pb, or the like. Specifically, in the present disclosure, an example in which Ag is applied will be described.

Specifically, Ag exhibits maximum transmittance in a wavelength range of 330 nm and has a property of transmitting certain light even at a thickness of roughly 1000 Å.

The first and second dielectric layers 233 and 237 can include a silicon nitride (SiNₓ) film/inkjet printing type PI, a monomer, or a silicon nitride (SiNₓ) film. But, the present disclosure is not limited thereto. Alternatively, the first and second dielectric layers 233 and 237 can include an inorganic material, an organic material, or a combination of the inorganic material and the organic material. But, the present disclosure is not limited thereto. The inorganic material can include a silicon nitride (SiNₓ) film, a silicon oxide (SiOₓ) film, an aluminum oxide (AlOₓ) film, IZO, ZnO, or ITO. But, the present disclosure is not limited thereto. Further, the organic material can further include a monomer, a polymer, polyimide (PI), or other organic materials. But, the present disclosure is not limited thereto.

An overall thickness of the color purifier layer 230 can range from 0.8 μm to 4 μm. But, the present disclosure is not limited thereto. Further, a thickness of the dielectric layer 233 can range from 0.4 μm to 2 μm. But, the present disclosure is not limited thereto.

The dielectric layer 233 can replace a function of an encapsulation layer (thin film encapsulation layer) of the organic light-emitting display device.

Further, black matrices 240 are formed on the third metal layer 239 located at the uppermost portion of the color purifier layer 230 to correspond to boundaries of adjacent sub-pixels R-SP, G-SP, and B-SP. The black matrix 240 can include a black resin or a double film of chromium oxide (CrOₓ) and chromium (Cr), but is not limited thereto.

Further, the red, green, and blue color filter layers 250R, 250G, and 250B are formed on the color purifier layer 230 located between the black matrices 240 and correspond to each of the sub-pixels R-SP, G-SP, and B-SP.

With reference to FIG. 5, in various embodiments of the present disclosure, another encapsulation layer can be formed on the third metal layer 239 to be interposed between the third metal layer 239 and the red, green, and blue color filter layers 250R, 250G, and 250B. The another encapsulation layer can perform the same function as the encapsulation layer 223 to protect the light-emitting element E by blocking moisture or oxygen introduced from the outside. Similarly, the another encapsulation layer can include an ultraviolet hardening sealant (UV sealant) or a frit sealant. Also, the another encapsulation layer can have a stacked structure of an inorganic film/an organic film/an inorganic film.

Also, with reference to FIG. 5, each of the first metal layer 231, the second metal layer 235 and the third metal layer 239 can be formed as a sheet that covers or overlaps each of the sub-pixels R-SP, G-SP, and B-SP. For example, the first metal layer 231, the second metal layer 235 and the third metal layer 239 can overlap or cover respective emission regions E of the sub-pixels R-SP, G-SP, and B-SP. In this regard, first metal layer 231, the second metal layer 235 and the third metal layer 239 do not include a hole or an opening in a location that overlap the emission region E or the red, green, and blue color filter layers 250R, 250G, and 250B, of the sub-pixels R-SP, G-SP, and B-SP, respectively, but the present disclosure is not limited thereto.

Also, with reference to FIGS. 7 and 8, each of first metal layer 231, the second metal layer 235 and the third metal layer 239 can have thicknesses that are the same within itself, but the present disclosure is not limited there to. For example, thicknesses in each of first metal layer 231, the second metal layer 235 and the third metal layer 239 can vary, where a thickness of a first portion overlapping the emission region E can be different from a thickness of a second portion overlapping the bank 217 or the black matrix 240. Accordingly, the first portion can have a thickness that is equal to, less than, or greater than that of the second portion.

Additionally, with reference to FIGS. 7 and 8, the first dielectric layer 233 and the second dielectric layer 237 can each have thicknesses that are the same within itself, but the present disclosure is not limited there to. For example, thicknesses in the first dielectric layer 233 can vary, where a thickness of a first portion overlapping the emission region E can be different from a thickness of a second portion overlapping the bank 217 or the black matrix 240. Accordingly, the first portion can have a thickness that is equal to, less than, or greater than that of the second portion. The second dielectric layer 237 can also have a first portion can have a thickness that is equal to, less than, or greater than that of a second portion.

Additionally, with reference to FIG. 7, each component of the color purifier layer 230 including the first and second dielectric layers 233 and 237, and the first, second and third metal layers 231, 235 and 239 are shown coplanar across the respective the sub-pixels R-SP, G-SP, and B-SP, but the present disclosure is not limited thereto. For example, a level of portions of the color purifier layer 230 respectively in the sub-pixels R-SP, G-SP, and B-SP can be the same or different. For example, a level of the color purifier layer 230 in the red sub-pixel R-SP can be different from that of the green and/or blue sub-pixels G-SP and B-SP. For example, the level of the color purifier layer 230 in the red sub-pixel R-SP can be higher than or lower than that of the green and/or blue sub-pixels G-SP and B-SP based on a thickness of the underlying portion of the encapsulation layer 223, and/or a level of the light-emitting element E, including that of the organic light-emitting layer 119. Meanwhile, thicknesses of the respective the first and second dielectric layers 233 and 237, and the first, second and third metal layers 231, 235 and 239 can be maintained to provide a ripple phenomenon due to a micro cavity phenomenon within each sub-pixels R-SP, G-SP, and B-SP.

FIG. 9 is a view illustrating the progress of light transmitted through the metal layers and the dielectric layer constituting the color purifier layer in FIG. 8.

Referring to FIG. 9, as light incident from the light-emitting element E on the color purifier layer 230 passes through the first and second dielectric layers 233 and 237 with thicknesses of at least 500 nm or more, a phenomenon in which transmittance of light fluctuates like a wave due to a ripple phenomenon occurs.

Further, light in a specific wavelength range can be amplified through the first to third metal layers 231, 235, and 239 with the first and second dielectric layers 233 and 237 of the thickness in which a ripple effect appears therebetween due to a micro cavity phenomenon.

Here, the micro cavity phenomenon means a phenomenon in which a light-emitting spectrum changes by a mutual light interference effect due to reflectivity of a reflective electrode and transmittance of a translucent electrode and a distance between the two electrodes, for example, the thickness of the dielectric layer.

The first to third metal layers 231, 235, and 239 amplify light in a specific wavelength range among light in which the ripple phenomenon in which the transmittance fluctuates like a wave through the first and second dielectric layers 233 and 237 occurs, and narrowly emit the light.

Finally, the narrow light emitted through the third metal layer 239 realizes a high color gamut through the red, green, and blue color filter layers 250R, 250G, and 250B.

Ultimately, light in the specific wavelength range among light emitted from the light-emitting element E is amplified through the color purifier layer 230 including the first metal layer 231, the first dielectric layer 233, the second metal layer 235, the second dielectric layer 237, and the third metal layer 239, and is narrowly emitted through the red, green, and blue color filter layers 250R, 250G, and 250B.

Accordingly, a light source which becomes narrow through the color purifier layer 230 can realize a high color gamut which may not be realized by conventional color filters while passing through the red, green, and blue color filter layers 250R, 250G, and 250B.

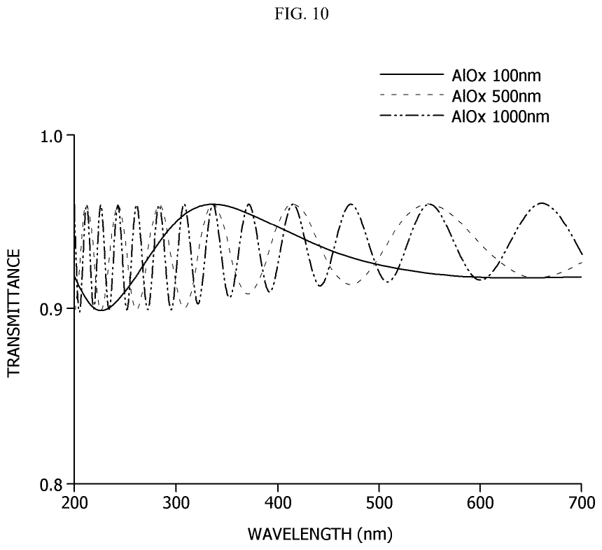

FIG. 10 is a view illustrating the progress of light transmission shown for each of thicknesses of the dielectric layers of the color purifier layers according to the first and second embodiments of the present disclosure.

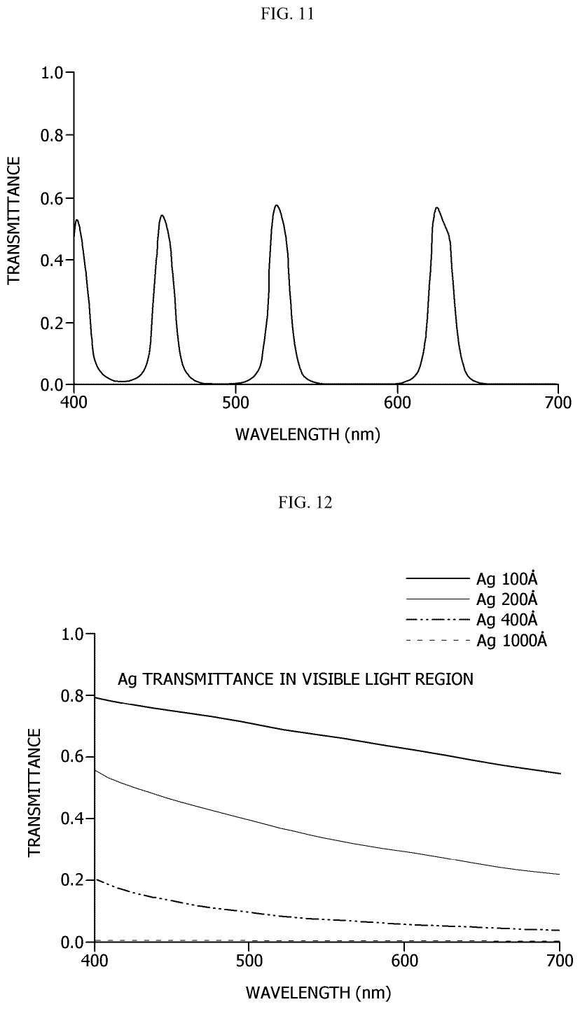

FIG. 11 is a view illustrating transmittance of the color purifier layers according to the first and second embodiments of the present disclosure.

As shown in FIG. 10, when an AlOₓ dielectric layer is formed with a thickness of roughly 500 nm or more, the ripple phenomenon occurs.

When the thickness of the dielectric layer is roughly 100 nm, the ripple phenomenon does not appear in the transmittance, but when the thickness of the dielectric layer is 500 nm or more, the ripple phenomenon in which a transmittance graph fluctuates like a wave appears.

Further, as shown in FIG. 11, when the metal layer composed of Ag of roughly 20 nm is formed on and under the AlOₓ dielectric layer with the thickness in which this ripple phenomenon appears, it can be seen that light in specific wavelength ranges, for example, wavelength ranges of roughly 470 nm, 530 nm, and 640 nm is amplified due to the micro cavity phenomenon, but is not limited thereto.

Accordingly, as shown in FIGS. 10 and 11, the color purifier layer serves to sharply and narrowly amplify light of a specific wavelength range due to the ripple phenomenon of the dielectric layers and the micro cavity phenomenon of the plurality of metal layers.

FIG. 12 is a view illustrating transmittance according to a wavelength range in a visible light region of the metal layers of the color purifier layer of the organic light-emitting display device according to the embodiment of the present disclosure.

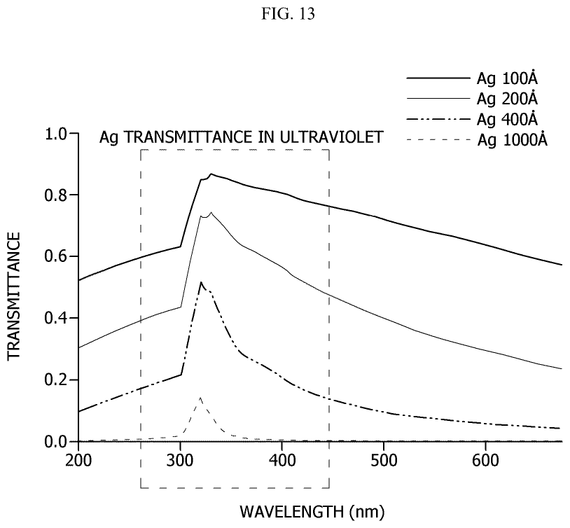

FIG. 13 is a view illustrating transmittance according to a wavelength range in an ultraviolet region of the metal layers of the color purifier layer of the organic light-emitting display device according to the embodiment of the present disclosure.

FIG. 12 is a case in which silver (Ag) applied as a material of the metal layers, and illustrates Ag transmittance in the visible light region when thicknesses of the Ag metal layer are applied as 100 Å, 200 Å, 400 Å, and 1000 Å.

As shown in FIG. 12, an Ag metal exhibits a certain semi transmission property in the visible light region when the thickness of the metal layer is roughly 100 Å to 300 Å, but when the thickness reaches roughly 1000 Å, the transmittance becomes 0%.

However, as shown in FIG. 13, when the transmittance of the Ag metal is widely looked at up to not only a range which can be seen by human eyes but also the ultraviolet region which is a region except for the visible light region, it can be seen that the transmittance exhibits a maximum value in a wavelength range of 330 nm, and transmits certain light even at the thickness of 1000 Å.

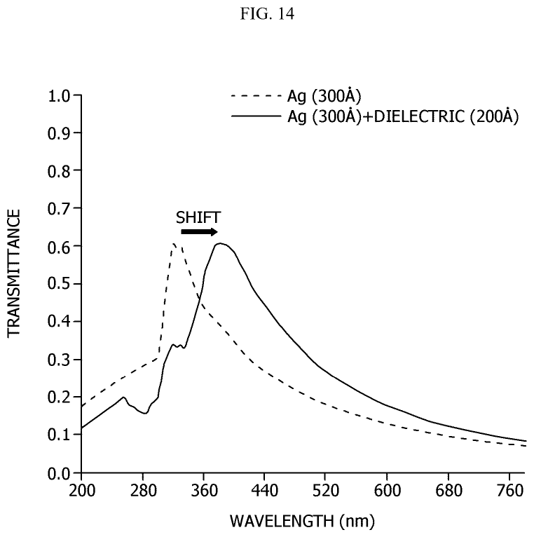

FIG. 14 is a view illustrating a state in which a transmittance peak is shifted by the dielectric layer of the color purifier layer of the organic light-emitting display device according to the embodiment of the present disclosure.

As shown in FIG. 14, as a result of checking transmittance changes of a case in which the color purifier layer using only the Ag metal layer is used and a case in which the color purifier layer using the dielectric layer stacked on the Ag metal layer is used, which is the embodiment of the present disclosure, it can be seen that a transmittance peak is shifted to the right when the dielectric layer is applied to the Ag metal layer compared to when only the Ag metal layer is used.

For example, when the Ag metal layer is used, the transmittance peak appears in a wavelength range of roughly 300 nm, but when the color purifier layer in which the dielectric layer is stacked on the Ag metal layer is used, which is the embodiment of the present disclosure, it can be seen that the transmittance peak appears in a wavelength range of roughly 400 nm. But the present disclosure is not limited thereto.

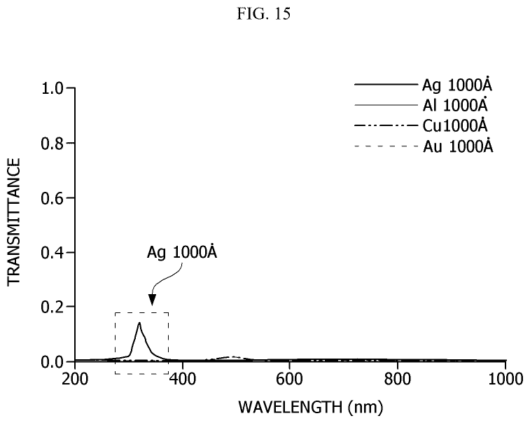

FIG. 15 is a view illustrating transmittance according to a metal material applied to the metal layer of the color purifier layer of the organic light-emitting display device according to the embodiment of the present disclosure.

As shown in FIG. 15, as a result of a transmittance simulation for Al, Cu, and Au metals of the same thickness to check whether light is transmitted at a thickness of 100 nm or more in metals other than Ag, it can be seen that the Ag metal used in the embodiment of the present disclosure exhibits the best transmittance effect, but transmittance effects are slightly exhibited in other metals.

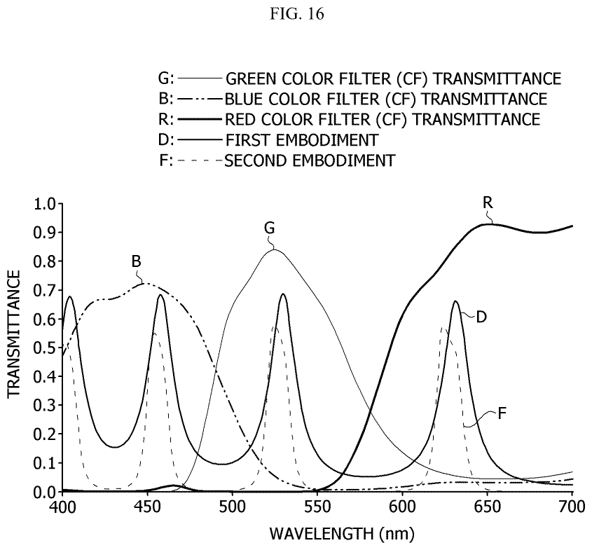

FIG. 16 is a view illustrating transmittance according to wavelengths of the color purifier layers the organic light-emitting display devices according to the first and second embodiments of the present disclosure.

As shown in FIG. 16, R represents transmittance in a wavelength range of roughly 660 to 700 nm when light passes through the red color filter layer 150R, G represents transmittance in a wavelength range of roughly 470 to 570 nm when light passes through the green color filter layer 150G, and B represents transmittance in a wavelength range of roughly 400 to 480 nm when light passes through the blue color filter layer 150B.

Further, D is a case of the first embodiment of the present disclosure, and represents transmittance for each wavelength range in a case in which the color purifier layer (130 in FIG. 4) composed of the first metal layer (131 in FIG. 4), the dielectric layer (133 in FIG. 4), and the second metal layer (135 in FIG. 4) is provided between the encapsulation layer (123 in FIG. 4) and the plurality of color filter layers (150R, 150G, and 150B in FIG. 4).

Further, F is a case of the second embodiment of the present disclosure, and represents transmittance for each wavelength range in a case in which the color purifier layer (230 in FIG. 7) composed of the first metal layer (231 in FIG. 7), the first dielectric layer (233 in FIG. 7), the second metal layer (235 in FIG. 7), the second dielectric layer (237 in FIG. 7), and the third metal layer (239 in FIG. 7) is provided between the encapsulation layer (223 in FIG. 7) and the plurality of color filters (250R, 250G, and 250B in FIG. 7).

As in the first and second embodiments of the present disclosure, it can be seen that a light source primarily emitted from the light-emitting element E changes to a light source in which the transmittance peak is sharp and narrow in specific wavelength ranges, for example, roughly 450 nm, 530 nm, and 640 nm while passing through each of the color purifier layer 130 of the first embodiment and the color purifier layer 230 of the second embodiment. But the present disclosure is not limited thereto.

FIG. 17 is a view illustrating a color gamut of the organic light-emitting display device according to the embodiment of the present disclosure.

As shown in FIG. 17, it can be seen that a color gamut is roughly 75.7% when a white color filter (White CF) is applied (H), and a color gamut is roughly 105.9% when R, G, and B are individually driven (I).

However, as in the first and second embodiments (D) of the present disclosure, it can be seen that a color gamut is shown as high as roughly 111.4% when the color purifier layer is disposed, as a single layer which is a stacked structure of the first metal layer, the dielectric layer, and the second metal layer, or multiple layers of a double-stacked structure of the first metal layer, the first dielectric layer, the second metal layer, the second dielectric layer, and the third metal layer, between the encapsulation layer and the color filter layers.

As in the embodiments of the present disclosure, since the color purifier layer composed of the metal layer and the dielectric layer is disposed under the color filter layers, light emitted from the light-emitting element is changed to a sharp and narrow light source while passing through the color purifier layer.

Accordingly, this sharp and narrow light source is emitted through the red, green, and blue color filters 150R, 150G, and 150B, and thus can realize a high color gamut which may not be realized by the conventional color filters.

Hereinafter, a manufacturing method of the organic light-emitting display device according to one embodiment of the present disclosure will be described.

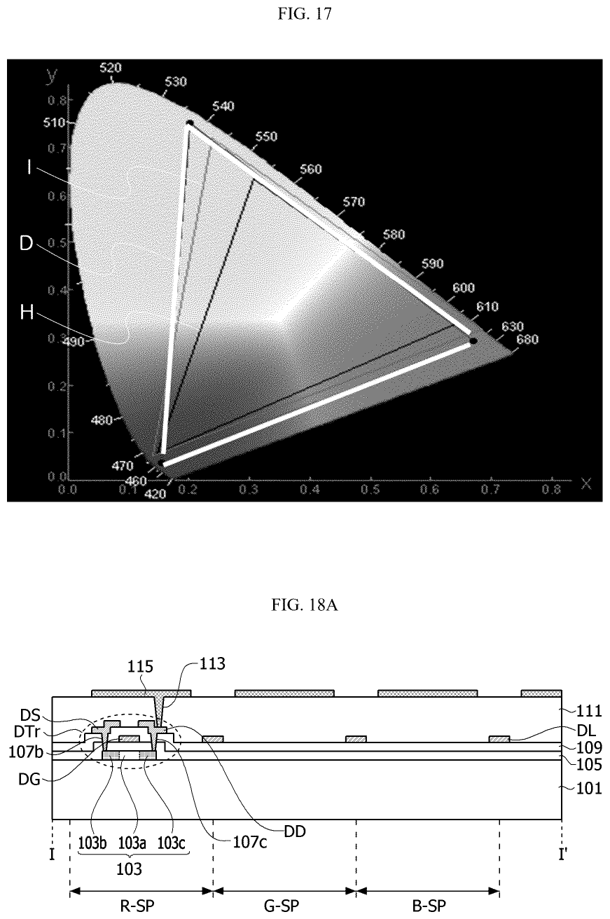

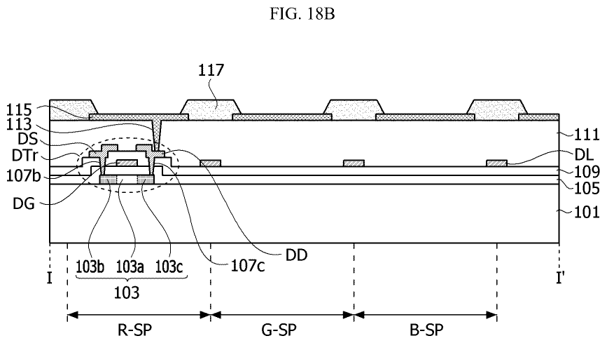

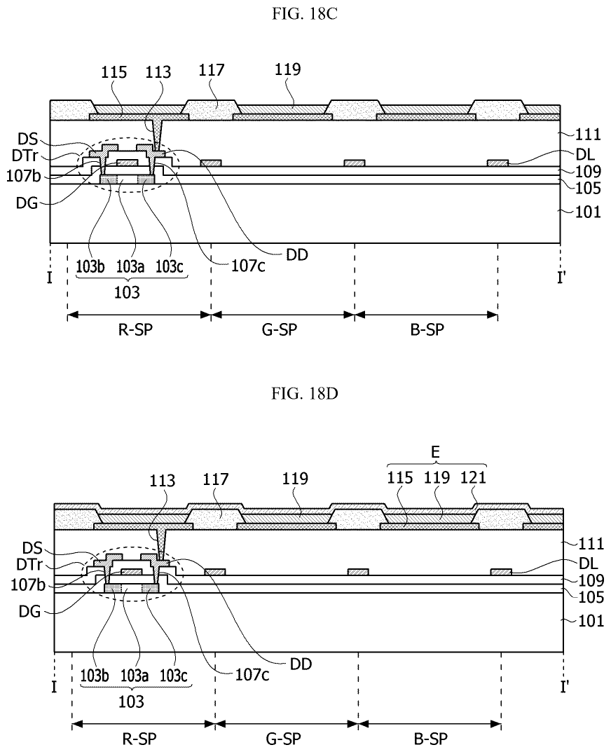

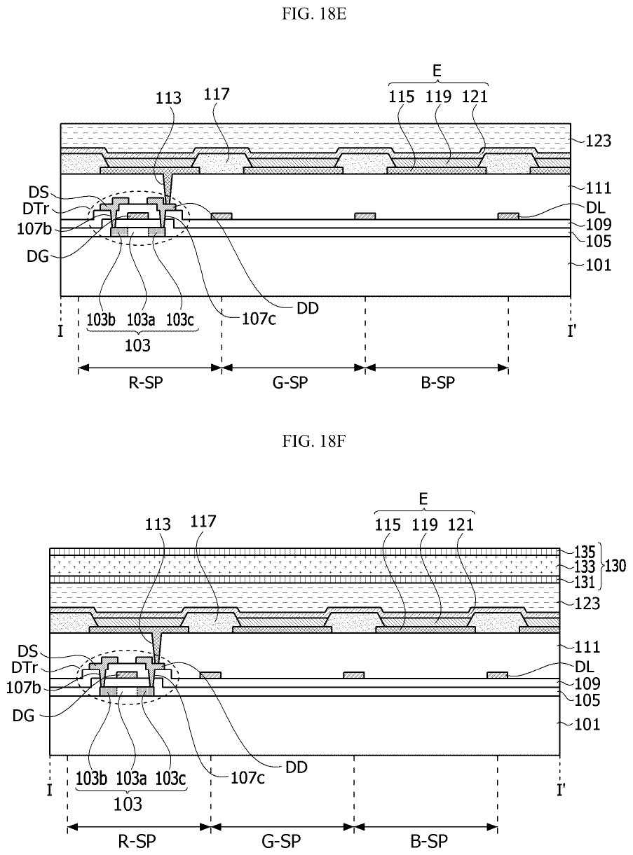

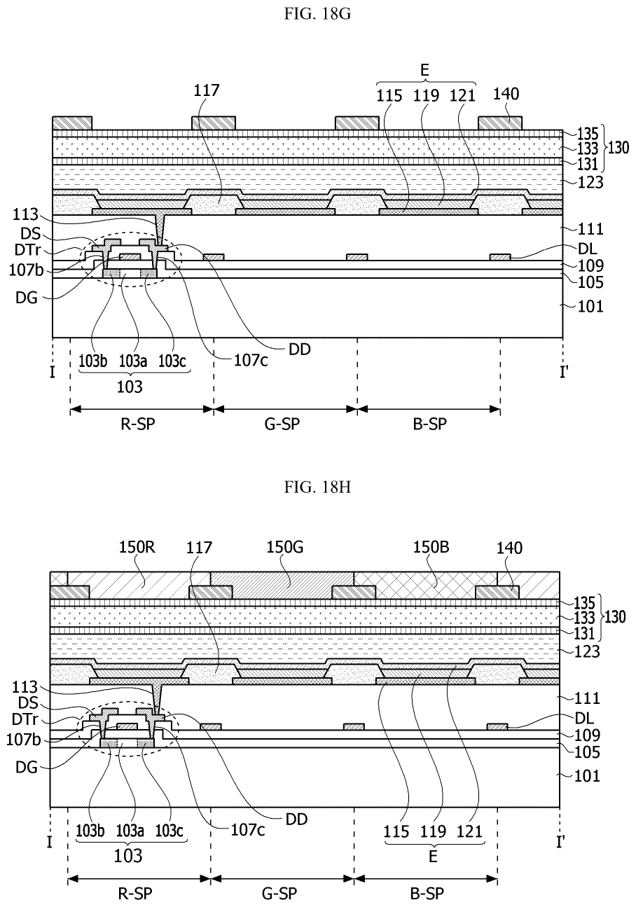

FIGS. 18A to 18H are cross-sectional views of manufacturing processes of the organic light-emitting display device according to one embodiment of the present disclosure.

Prior to description, the manufacturing method of the organic light-emitting display device 100 according to one embodiment of the present disclosure has a feature in a process of forming the color purifier layer (130 in FIG. 4) between the light-emitting element E and the color filter layers, and a process of forming the driving thin film transistor DTr is not much different from a conventional manufacturing method and thus a content thereof will be briefly described, and the description will focus on a part which manufactures the color purifier layer between the light-emitting element E and the color filter layers which are main parts of the present disclosure.

Referring to FIG. 18A, on a substrate 101, a driving thin film transistor DTr including source and drain electrodes DS and DD, a semiconductor layer 103 including source and drain regions 103b and 103c in contact with these electrodes DS and DD, and a gate insulating film 105 and a gate electrode DG located on the semiconductor layer 103, and first and second interlayer insulating films 109 and 111 in contact with the drain electrode DD of the driving thin film transistor DTr are provided, and a drain contact hole 113 is provided in the second interlayer insulating film 111.

In more detailed description, the semiconductor layer 103 is located on a switching region of each of the sub-pixels R-SP, G-SP, and B-SP on the substrate 101. The semiconductor layer 103 is made of silicon, and includes an active region 103a forming a channel at a central portion thereof, and source and drain regions 103b and 103c doped with a high concentration of impurities at both side surfaces of the active region 103a.

Next, the gate insulating film 105 is formed on the semiconductor layer 103.

Next, the gate line (GL in FIG. 2) and the gate electrode DG are formed in one direction on the gate insulating film 105 to correspond to the active region 103a of the semiconductor layer 103.

Next, the first interlayer insulating film 109 is formed on the gate insulating film 105 including the gate electrode DG and the gate line GL. The first interlayer insulating film 109 and the gate insulating film 105 under the first interlayer insulating film 109 include first and second semiconductor layer contact holes 107b and 107c which respectively expose the source and drain regions 103b and 103c located at both side surfaces of the active region 103a.

In this case, the first interlayer insulating film 109 can be formed of an inorganic insulating material such as silicon oxide (SiOₓ) or silicon nitride (SiNₓ), or an organic insulating material such as photo acryl or benzocyclobutene to planarize the substrate 101. But, the present disclosure is not limited thereto.

Next, the source and drain electrodes DS and DD which are spaced apart from each other and respectively in contact with the source and drain regions 103b and 103c exposed through the first and second semiconductor layer contact holes 107b and 107c are formed on the first interlayer insulating film 109 including the first and second semiconductor layer contact holes 107b and 107c.

In this case, the source and drain electrodes DS and DD, the semiconductor layer 103 including the source and drain regions 103b and 103c in contact with these electrodes DS and DD, and the gate insulating film 105 and the gate electrode DG located on the semiconductor layer 103 form the driving thin film transistor DTr.

The switching thin film transistor STr has the same structure as the driving thin film transistor DTr and is connected to the driving thin film transistor DTr.

Further, in the drawing, the switching thin film transistor STr and the driving thin film transistor DTr are exemplified in a top gate type in which the semiconductor layer 103 includes a polysilicon semiconductor layer or an oxide semiconductor layer, and can be provided as a bottom gate type composed of pure and impure amorphous silicon as a modified example thereof. But, the present disclosure is not limited thereto.

Next, when the semiconductor layer 103 includes an oxide semiconductor layer, a light-shielding layer can be further located under the semiconductor layer 103, and a buffer layer can be located between the light-shielding layer and the semiconductor layer 103.

Next, the second interlayer insulating film 111 is formed on the source and drain electrodes DS and DD and the first interlayer insulating film 109 exposed between the two electrodes DS and DD.

In this case, the second interlayer insulating film 111 can be formed of an inorganic insulating material such as silicon oxide (SiOₓ) or silicon nitride (SiNₓ), or formed of an organic insulating material such as photo acryl or benzocyclobutene to planarize the substrate 101. But, the present disclosure is not limited thereto.

Meanwhile, an insulating film composed of an inorganic insulating material such as silicon oxide (SiOₓ) or silicon nitride (SiNₓ) can be further formed between the second interlayer insulating film 111 and the source and drain electrodes DS and DD. But, the present disclosure is not limited thereto.

Next, the second interlayer insulating film 111 is selectively etched through a mask process using a photolithography technology to form the drain contact hole 113 which exposes the drain electrode DD.

Next, a first electrode 115 is formed of a conductive material with a relatively high work function in each of the sub-pixels R-SP, G-SP, and B-SP on the second interlayer insulating film 111. The first electrode 115 in each of the sub-pixels R-SP, G-SP, and B-SP is connected to the drain electrode DD of the driving thin film transistor DTr through the drain contact hole 113, and for example, an anode of a light-emitting element E includes a transparent material with a relatively high work function value. But the present disclosure is not limited thereto.

The first electrode 115 is located for each of the sub-pixels R-SP, G-SP, and B-SP.

The first electrode 115 can include at least one stacked structure or at least one selected from the group including indium tin oxide (ITO), indium zinc oxide (IZO), zinc oxide (ZnO), indium oxide (In₂O₃), indium gallium oxide (IGO), and aluminum zinc oxide (AZO). However, the present disclosure is not limited thereto.

Meanwhile, the organic light-emitting display device according to the first embodiment of the present disclosure can be a top emission type in which light from the light-emitting element E is output in an opposite direction to the substrate 101. Accordingly, the first electrode 115 can further include a reflective electrode or reflective layer formed of a metal material with a high reflectivity under the transparent conductive material. For example, the reflective electrode or reflective layer can include an aluminum-palladium-copper (APC) alloy or silver (Ag). In this case, the first electrode 115 can have a triple-layer structure of ITO/APC/ITO or ITO/Ag/ITO, but is not limited thereto.

Next, referring to FIG. 18B, an insulating material layer is formed to form a bank, and then a bank 117 is formed by selectively etching the insulating material layer through a mask process using a photolithography technology on the second interlayer insulating film 111 including the first electrode 115.

In this case, the bank 117 overlaps and covers an edge of the first electrode 115 and exposes a central portion of the first electrode 115. This bank 117 can be formed of an inorganic insulating material. For example, the bank 117 can be formed of silicon oxide (SiOₓ) or silicon nitride (SiNₓ). But, the present disclosure is not limited thereto.

On the other hand, the bank 117 can be formed of an organic insulating material, but is not limited thereto.

The organic insulating material can include one or more among photoresist, polyacrylates resin, epoxy resin, phenolic resin, polyamides resin, polyimides resin, unsaturated poly ester resin, polyphenylene ether resin, polyphenylene sulfide resin, and benzocyclobutene. But, the present disclosure is not limited thereto.

Next, referring to FIG. 18C, a light-emitting layer 119 is formed on the first electrode 115 exposed through the bank 117. The light-emitting layer 119 can emit white light.

The light-emitting layer 119 can include a first charge auxiliary layer, a light-emitting material layer, and a second charge auxiliary layer sequentially located from an upper portion of the first electrode 115. The light-emitting material layer can have a single-layer or multi-layer structure including at least one of red, green, and blue light-emitting materials, but is not limited thereto. When the light-emitting material layer has a multi-layer structure, a charge generation layer (charge or first or second charge auxiliary layer) can be further formed between the light-emitting material layers. Here, the light-emitting material can be an organic light-emitting material such as a phosphorescent compound or fluorescent compound, or an inorganic light-emitting material such as a quantum dot. But, the present disclosure is not limited thereto.

The first charge auxiliary layer can be a hole auxiliary layer, and the hole auxiliary layer can include at least one of a hole injecting layer (HIL) and a hole transporting layer (HTL). Further, the second charge auxiliary layer can be an electron auxiliary layer, and the electron auxiliary layer can include at least one of an electron injecting layer (EIL) and an electron transporting layer (ETL). However, the present disclosure is not limited thereto.

The light-emitting layer 119 can be formed through a vacuum thermal evaporation process. Here, the light-emitting layer 119 is shown to be formed between the adjacent banks 117, but the light-emitting layer 119 can be formed substantially on the entire surface of the substrate 101. For example, the light-emitting layer 119 can also be formed on the banks 117. But the present disclosure is not limited thereto.

Alternatively, the light-emitting layer 119 can be formed through a solution process, and a spin coating method, inkjet printing method, or screen printing method can be used as the solution process. But, the present disclosure is not limited thereto.

Next, referring to FIG. 18D, a second electrode 121 composed of a conductive material with a relatively low work function is formed the entire surface of the substrate 101 including the light-emitting layer 119 and the banks 117. Here, the second electrode 121 can be formed of aluminum, magnesium, silver, or an alloy thereof. But, the present disclosure is not limited thereto. In this case, the second electrode 121 has a relatively thin thickness so that light from the light-emitting layer 119 can be transmitted. On the other hand, the second electrode 121 can be formed of a transparent conductive material such as indium-gallium-oxide (IGO). But, the present disclosure is not limited thereto.

The first electrode 115, the light-emitting layer 119, and the second electrode 121 form the light-emitting element E. Here, the first electrode 115 can function as an anode and the second electrode 121 can function as a cathode, but the present disclosure is not limited thereto.

As mentioned above, the organic light-emitting display device 100 according to the first embodiment of the present disclosure can be a top emission type in which light from the light-emitting layer 119 of the light-emitting element E output in the opposite direction to the substrate 101, for example, to the outside through the second electrode 121. The top emission type can have a wider emission region than the bottom emission type of the same area, and thus can improve brightness and lower power consumption.

Next, referring to FIG. 18E, an encapsulation layer 123 is formed on the second electrode 121. The encapsulation layer 123 protects the light-emitting element E by blocking moisture or oxygen introduced from the outside. The encapsulation layer 123 can include an ultraviolet hardening sealant (UV sealant) or frit sealant. On the other hand, the encapsulation layer 123 can have a stacked structure of an inorganic film/an organic film/an inorganic film. But, the present disclosure is not limited thereto.

Next, referring to FIG. 18F, a first metal layer 131, a dielectric layer 133, and a second metal layer 135 are sequentially stacked on the encapsulation layer 123. In this case, the first metal layer 131, the dielectric layer 133, and the second metal layer 135 form a color purifier layer 130.

The first and second metal layers 131 and 135 serve to amplify light in a specific wavelength range and make light narrow.

Further, when the thickness of the dielectric layer 133 becomes at least 500 nm or more, a ripple phenomenon in which transmittance fluctuates like a wave occurs.

In this case, the color purifier layer 130 amplifies and emits light in a specific wavelength range due to a ripple phenomenon of the dielectric layer 133 and a micro cavity phenomenon of the first and second metal layers 131 and 135.

Further, the first and second metal layers 131 and 135 have thicknesses in a range of 10 nm to 100 nm. The first metal layer 131 and the second metal layer 135 can have the same thickness. However, the present disclosure is not necessarily limited thereto.

Further, the materials of the first to third metal layers 231, 235, and 239 can include Ag or an Ag alloy. The Ag alloy materials can contain Ag and at least one of Yb, Mg, Al, Au, Cu, Pb, or the like. But, the present disclosure is not limited thereto. Specifically, in present disclosure, an example in which Ag is applied will be described.

Ag exhibits maximum transmittance in a wavelength range of 330 nm and has a property of transmitting certain light even at a thickness of roughly 1000 Å.

The dielectric layer 133 can include a silicon nitride (SiNₓ) film/inkjet printing type PI, a monomer, or a silicon nitride (SiNₓ) film. But, the present disclosure is not limited thereto. Alternatively, the dielectric layer 133 can include an inorganic material, an organic material, or a combination of the inorganic material and the organic material. But, the present disclosure is not limited thereto. The inorganic material can include a silicon nitride (SiNₓ) film, a silicon oxide (SiOₓ) film, an aluminum oxide (AlOₓ) film, or an oxide film of IZO, ZnO, or ITO. But, the present disclosure is not limited thereto. Further, the organic material can further include a monomer, a polymer, polyimide (PI), or other organic materials. However, the present disclosure is not limited thereto.

The overall thickness of the color purifier layer 130 can range from 0.4 μm to 2 μm. But, the present disclosure is not limited thereto. Further, the thickness of the dielectric layer 133 can range from 0.4 μm to 2 μm. But, the present disclosure is not limited thereto.

The dielectric layer 133 can replace a function of an encapsulation layer (thin film encapsulation layer) of the organic light-emitting display device.

Next, referring to FIG. 18G, black matrices 140 are formed on the color purifier layer to correspond to boundaries of adjacent sub-pixels R-SP, G-SP, and B-SP. The black matrix 140 can include a black resin or a double film of chromium oxide (CrOₓ) and chromium (Cr), but is not limited thereto.

Next, referring to FIG. 18H, as the red, green, and blue color filter layers 150R, 150G, and 150B are formed on the color purifier layer 130 located between the black matrices 140 and correspond to each of the sub-pixels R-SP, G-SP, and B-SP, the manufacturing processes of the organic light-emitting display device according to the embodiment of the present disclosure is completed.

Hereinafter, an organic light-emitting display device according to a third embodiment of the present disclosure will be described.

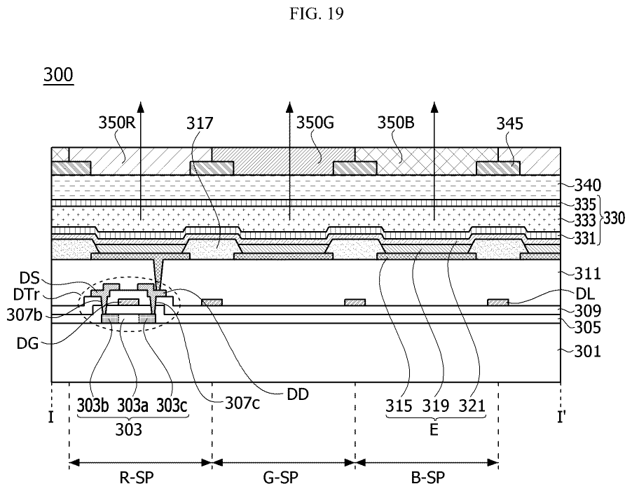

FIG. 19 is a cross-sectional view of the organic light-emitting display device according to the third embodiment of the present disclosure.

In an organic light-emitting display device 300 according to the third embodiment of the present disclosure, only a position where a color purifier layer 330 is disposed is different from the first and second embodiments of the present disclosure, and all other configurations are the same as the configurations of the first embodiment.

For example, the third embodiment is a case in which the color purifier layer 330 is disposed on a light-emitting element E and an encapsulation layer 340 is disposed on the color purifier layer 330 unlike the first and second embodiments.

Referring to FIG. 19, a semiconductor layer 303 is located on a switching region of each of the sub-pixels R-SP, G-SP, and B-SP on a substrate 301.

The semiconductor layer 303 is made of silicon, and includes an active region 303a forming a channel at a central portion thereof, and source and drain regions 303b and 303c doped with a high concentration of impurities at both side surfaces of the active region 303a.

A gate insulating film 305 is disposed on the semiconductor layer 303.

A gate electrode DG and a gate line GL are disposed in one direction on the gate insulating film 305 to correspond to the active region 303a of the semiconductor layer 303.

A first interlayer insulating film 309 is disposed on the gate insulating film 305 including the gate electrode DG and the gate line GL. The first interlayer insulating film 309 and the gate insulating film 305 under the first interlayer insulating film 309 include first and second semiconductor layer contact holes 307b and 307c which respectively expose the source and drain regions 303b and 303c located at both side surfaces of the active region 303a.

The first interlayer insulating film 309 can be formed of an inorganic insulating material such as silicon oxide (SiOₓ) or silicon nitride (SiNₓ), or an organic insulating material such as photo acryl or benzocyclobutene to planarize the substrate 301. But, the present disclosure is not limited thereto.

Source and drain electrodes DS and DD which are spaced apart from each other and respectively in contact with the source and drain regions 303b and 303c exposed through the first and second semiconductor layer contact holes 307b and 307c are provided on the first interlayer insulating film 309 including the first and second semiconductor layer contact holes 307b and 307c.

The source and drain electrodes DS and DD, the semiconductor layer 303 including the source and drain regions 303b and 303c in contact with these electrodes DS and DD, and the gate insulating film 305 and the gate electrode DG located on the semiconductor layer 303 form a driving thin film transistor DTr.

Meanwhile, the switching thin film transistor (STr in FIG. 2) has the same structure as the driving thin film transistor DTr and is connected to the driving thin film transistor DTr.

Further, in the drawing, the switching thin film transistor STr and the driving thin film transistor DTr are exemplified in a top gate type in which the semiconductor layer 303 includes a polysilicon semiconductor layer or an oxide semiconductor layer. The switching thin film transistor STr and the driving thin film transistor DTr can be provided as a bottom gate type composed of pure and impure amorphous silicon as a modified example thereof.

The switching thin film transistor STr can be further formed in each of the sub-pixels R-SP, G-SP, and B-SP on the substrate 301. In this case, the gate electrode DG of the driving thin film transistor DTr is connected to a drain electrode of the switching thin film transistor STr, and a source electrode SS of the driving thin film transistor DTr is connected to a power line. Further, a gate electrode and a source electrode of the switching thin film transistor STr can be respectively connected to the gate line and the data line, but are not limited thereto.

In addition, one or more sensing thin film transistors with the same structure as the driving thin film transistor DTr can be further formed in each of the sub-pixels R-SP, G-SP, and B-SP on the substrate 301.

When the semiconductor layer 303 includes an oxide semiconductor layer, a light-shielding layer can be further located under the semiconductor layer 303, and a buffer layer can be located between the light-shielding layer and the semiconductor layer 303.

Further, a second interlayer insulating film 311 is disposed on the source and drain electrodes DS and DD and the first interlayer insulating film 309 exposed between the two electrodes DS and DD.

The second interlayer insulating film 311 can be formed of an inorganic insulating material such as silicon oxide (SiOₓ) or silicon nitride (SiNₓ), or formed of an organic insulating material such as photo acryl or benzocyclobutene to planarize the substrate 301. But, the present disclosure is not limited thereto.

Meanwhile, an insulating film composed of an inorganic insulating material such as silicon oxide (SiO₂) or silicon nitride (SiNₓ) can be further formed between the second interlayer insulating film 311 and the source and drain electrodes DS and DD.

A first electrode 315 is formed of a conductive material with a relatively high work function in each of the sub-pixels R-SP, G-SP, and B-SP on the second interlayer insulating film 311. The first electrode 315 in each of the sub-pixels R-SP, G-SP, and B-SP is connected to the drain electrode DD of the driving thin film transistor DTr through a drain contact hole 313, and for example, an anode of the light-emitting element E includes a transparent material with a relatively high work function value.

The first electrode 315 is located for each of the sub-pixels R-SP, G-SP, and B-SP.

The first electrode 315 can include at least one stacked structure or at least one selected from the group including indium tin oxide (ITO), indium zinc oxide (IZO), zinc oxide (ZnO), indium oxide (In₂O₃), indium gallium oxide (IGO), and aluminum zinc oxide (AZO). However, the present disclosure is not limited thereto.

Meanwhile, the organic light-emitting display device 300 according to the third embodiment of the present disclosure can be a top emission type in which light from the light-emitting element E is output in an opposite direction to the substrate 301. Accordingly, the first electrode 315 can further include a reflective electrode or reflective layer formed of a metal material with high reflectivity under a transparent conductive material. For example, the reflective electrode or reflective layer can include an aluminum-palladium-copper (APC) alloy or silver (Ag). But, the present disclosure is not limited thereto. In this case, the first electrode 315 can have a triple-layer structure of ITO/APC/ITO or ITO/Ag/ITO, but is not limited thereto.

A bank 317 is formed of an insulating material on the first electrode 315. The bank 317 overlaps and covers an edge of the first electrode 315 and exposes a central portion of the first electrode 315. This bank 317 can be formed of an inorganic insulating material. For example, the bank 317 can be formed of silicon oxide (SiOₓ) or silicon nitride (SiNₓ). But, the present disclosure is not limited thereto.

On the other hand, the bank 317 can be formed of an organic insulating material, but is not limited thereto.

The organic insulating material can include one or more among photoresist, polyacrylates resin, epoxy resin, phenolic resin, polyamides resin, polyimides resin, unsaturated polyesters resin, polyphenylene ether resin, polyphenylene sulfide resin, and benzocyclobutene. But, the present disclosure is not limited thereto.

A light-emitting layer 319 is formed on the first electrode 315 exposed through the bank 317. The light-emitting layer 319 can emit white light.

The light-emitting layer 319 can include a first charge auxiliary layer, a light-emitting material layer, and a second charge auxiliary layer sequentially located from an upper portion of the first electrode 315. The light-emitting material layer can have a single-layer or multi-layer structure including at least one of red, green, and blue light-emitting materials. However, the present disclosure is not limited thereto. When the light-emitting material layer has a multi-layer structure, a charge generation layer (charge or first or second charge auxiliary layer) can be further formed between the light-emitting material layers. Here, the light-emitting material can be an organic light-emitting material such as a phosphorescent compound or fluorescent compound, or an inorganic light-emitting material such as a quantum dot. But, the present disclosure is not limited thereto.

The first charge auxiliary layer can be a hole auxiliary layer, and the hole auxiliary layer can include at least one of a hole injecting layer (HIL) and a hole transporting layer (HTL). Further, the second charge auxiliary layer can be an electron auxiliary layer, and the electron auxiliary layer can include at least one of an electron injecting layer (EIL) and an electron transporting layer (ETL). However, the present disclosure is not limited thereto.

The light-emitting layer 319 can be formed through a vacuum thermal evaporation process. Here, the light-emitting layer 319 is shown to be formed in the bank 317, but the light-emitting layer 319 can be formed substantially on the entire surface of the substrate 301. For example, the light-emitting layer 319 can also be formed on the bank 317.

Alternatively, the light-emitting layer 319 can be formed through a solution process, and a spin coating method, an inkjet printing method, or a screen printing method can be used as the solution process. But, the present disclosure is not limited thereto.

On the-light-emitting layer 319, a second electrode 321 composed of a conductive material with a relatively low work function is formed substantially on the entire surface of the substrate 301. Here, the second electrode 321 can be formed of aluminum, magnesium, silver, or an alloy thereof. But, the present disclosure is not limited thereto. In this case, the second electrode 321 has a relatively thin thickness so that light from the light-emitting layer 319 can be transmitted. On the other hand, the second electrode 321 can be formed of a transparent conductive material such as indium-gallium-oxide (IGO). But, the present disclosure is not limited thereto.

The first electrode 315, the light-emitting layer 319, and the second electrode 321 form the light-emitting element E. Here, the first electrode 315 can function as an anode and the second electrode 321 can function as a cathode, but the present disclosure is not limited thereto.

The organic light-emitting display device 300 according to the third embodiment of the present disclosure can be a top emission type in which light from the light-emitting layer 319 of the light-emitting element E output in the opposite direction to the substrate 301, for example, to the outside through the second electrode 321. The top emission type can have a wider emission region than the bottom emission type of the same area, and thus can improve brightness and lower power consumption.

The color purifier layer 330 including a first metal layer 331, a dielectric layer 333, and a second metal layer 335 is formed on the light-emitting element E.

In this case, the color purifier layer 330 amplifies and emits light in a specific wavelength range due to a ripple phenomenon of the dielectric layer 333 and a micro cavity phenomenon of the first and second metal layers 331 and 335.

The light in the specific wavelength range amplified through the color purifier layer 330 is emitted through red, green, and blue color filter layers 350R, 350G, and 350B.

The first and second metal layers 331 and 335 have thicknesses in a range of 10 nm to 100 nm. Further, materials of the first and second metal layers 331 and 335 can include Ag or an Ag alloy. Ag alloy materials can contain Ag and at least one of Yb, Mg, Cu, Al, Au, Pb, or the like. But, the present disclosure is not limited thereto. Specifically, in present disclosure, an example in which Ag is applied will be described.

Ag exhibits maximum transmittance in a wavelength range of 330 nm and has a property of transmitting certain light even at a thickness of roughly 1000 Å.

The dielectric layer 333 can include a silicon nitride (SiNₓ) film/inkjet printing type PI, a monomer, or a silicon nitride (SiNₓ) film. But, the present disclosure is not limited thereto. Alternatively, the dielectric layer 333 can include an inorganic material, an organic material, or a combination of the inorganic material and the organic material. But, the present disclosure is not limited thereto. The inorganic material can include a silicon nitride (SiNₓ) film, an oxide (SiOₓ) film, an aluminum oxide (AlOₓ) film, IZO, ZnO, or ITO. But, the present disclosure is not limited thereto. Further, the organic material can further include a monomer, a polymer, polyimide (PI), or other organic materials. But, the present disclosure is not limited thereto.

An overall thickness of the color purifier layer 330 can range from 0.4 μm to 2 μm. But, the present disclosure is not limited thereto. Further, a thickness of the dielectric layer 333 can range from 0.4 μm to 2 μm. But, the present disclosure is not limited thereto.

The dielectric layer 333 can replace a function of an encapsulation layer (thin film encapsulation layer) of the organic light-emitting display device.

Also, the dielectric layer 333 can have thicknesses that are the same within itself, but the present disclosure is not limited there to. For example, thicknesses in the dielectric layer 333 can vary, where a thickness of a first portion overlapping the emission region E can be different from a thickness of a second portion overlapping the bank 317 or the black matrix 345. Within the second portion overlapping the bank 317, the black matrix 345, or a contact area between adjacent pair of color filters among the color filters 350R, 350G, 350B, the ripple phenomenon can be different from that of the first portion, and transmittance peaks at different wavelength ranges can be provided.

Meanwhile, as another embodiment of the present disclosure, the color purifier layer 330 can be used as a second electrode of the light-emitting element E. For example, the first metal layer 317 can be substituted for the second electrode 321. In such an instance, the first metal layer 317 can be entirely level across each of the sub-pixels R-SP, G-SP, and B-SP, or can be at a different level at locations overlapping the bank 317, the black matrix 345, or the contact area between adjacent pair of color filters among the color filters 350R, 350G, 350B.

Further, the encapsulation layer 340 is formed on the second metal layer 335 of the color purifier layer 330. The encapsulation layer 340 protects the light-emitting element E by blocking moisture or oxygen introduced from the outside. The encapsulation layer 340 can include an ultraviolet hardening sealant (UV sealant) or a frit sealant. But, the present disclosure is not limited thereto. On the other hand, the encapsulation layer 340 can have a stacked structure of an inorganic film/an organic film/an inorganic film. But, the present disclosure is not limited thereto.

Meanwhile, as still another embodiment of the present disclosure, the color purifier layer 330 can be formed in the encapsulation layer 340.

Black matrices 345 are formed on the encapsulation layer 340 to correspond to boundaries of adjacent sub-pixels R-SP, G-SP, and B-SP. The black matrix 345 can include a black resin or a double film of chromium oxide (CrOₓ) and chromium (Cr), but is not limited thereto.

The red, green, and blue color filter layers 350R, 350G, and 350B are formed on the encapsulation layer 340 located between the black matrices 345 and correspond to each of the sub-pixels R-SP, G-SP, and B-SP.

Accordingly, a light source narrowed by amplifying the light in the specific wavelength through the color purifier layer 330 can realize a high color gamut which may not be realized by conventional color filters while being emitted through the encapsulation layer 340 and the red, green, and blue color filter layers 350R, 350G, and 350B.

The organic light-emitting display device according to the embodiment of the present disclosure can be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical apparatus, a desktop personal computer (PC), a laptop PC, a laptop PC, a netbook computer, a workstation, a navigation device, a vehicle display device s, a theater display device, a television, a wallpaper apparatus, a signage apparatus, a gaming apparatus, a monitor, a camera, a camcorder, a home appliance, and the like. But, the present disclosure is not limited thereto.

An organic light-emitting display device according to various embodiments of the present disclosure can be described as follows.

An organic light-emitting display device according to one embodiment of the present disclosure can comprise a substrate where a plurality of pixel regions are defined, a light-emitting element formed in each of the plurality of pixel regions of the substrate, a color filter layer including red, green, and blue color filters located on the light-emitting elements to correspond to each of the plurality of pixel regions, and a color purifier layer located between the light-emitting element and the color filter layer and including at least two metal layers and at least one dielectric layer.

According to one embodiment of the present disclosure, the color purifier layer can include a stacked structure of a first metal layer, the dielectric layer, and a second metal layer.

According to one embodiment of the present disclosure, the color purifier layer can have a thickness of 0.4 μm to 2 μm.

According to one embodiment of the present disclosure, the metal layer can have a thickness of 10 nm to 100 nm.

According to one embodiment of the present disclosure, the color purifier layer can include a stacked structure of a first metal layer, a first dielectric layer, a second metal layer, a second dielectric layer, and a third metal layer.

According to one embodiment of the present disclosure, a thickness of the second metal layer can be twice or less a thickness of the first metal layer.

According to one embodiment of the present disclosure, a thickness of the second metal layer can be the sum of a thickness of the first metal layer and a thickness of the third metal layer.

According to one embodiment of the present disclosure, the metal layer can include Ag or an Ag alloy.

According to one embodiment of the present disclosure, the Ag alloy can contain Ag and at least one of Yb, Mg, Cu, Al, Au and Pb.

According to one embodiment of the present disclosure, the dielectric layer can include an oxide including SiNₓ, SiOₓ, AlOₓ, IZO, ZnO, or ITO, an organic material including a monomer, a polymer, or polyimide (PI), or a combination of the oxide and the organic material.

According to one embodiment of the present disclosure, an encapsulation layer can be further disposed between the color purifier layer and the light-emitting element or between the color purifier layer and the color filter layer.

According to one embodiment of the present disclosure, an encapsulation layer can be further disposed between the light-emitting element and the color filter layer; and the color purifier layer can be disposed in the encapsulation layer.

According to one embodiment of the present disclosure, the color purifier layer can be disposed in contact with the light-emitting element and the color filter layer.

Since the contents of the disclosure described in the above-described
technical problem, technical solution, and advantageous effects do not specify the essential features of the claims, the scope of the claims is not limited by the items described in the contents of the disclosure.

Although embodiments of the present invention have been described in detail with reference to the accompanying drawings, the present invention is not necessarily limited to these embodiments, and various modifications can be carried out without departing from the technical spirit of the present invention. Therefore, the embodiments disclosed in the present invention are not intended to limit the technical spirit of the present invention, but for describing it, and the scope of the technical spirit of the present invention is not limited by these embodiments. It should be understood that the above-described embodiments are illustrative and not restrictive in all respects.

What is claimed is:

1. An organic light-emitting display device comprising:
a substrate including a plurality of pixel regions;
a light-emitting element formed in each of the plurality of pixel regions of the substrate;
a color filter layer including red, green, and blue color filters located on the light-emitting elements to correspond to each of the plurality of pixel regions; and
a color purifier layer located between the light-emitting element and the color filter layer and including at least two metal layers and at least one dielectric layer.

2. The organic light-emitting display device of claim 1, wherein the color purifier layer includes a stacked structure of a first metal layer, the dielectric layer, and a second metal layer.

3. The organic light-emitting display device of claim 2, wherein the color purifier layer has a thickness of about 0.4 μm to about 2 μm.

4. The organic light-emitting display device of claim 1, wherein each of the at least two metal layers has a thickness of about 10 nm to about 100 nm.

5. The organic light-emitting display device of claim 1, wherein the color purifier layer includes a stacked structure of a first metal layer, a first dielectric layer, a second metal layer, a second dielectric layer, and a third metal layer.

6. The organic light-emitting display device of claim 5, wherein a thickness of the second metal layer is twice or less of a thickness of the first metal layer.

7. The organic light-emitting display device of claim 5, wherein a thickness of the second metal layer is a sum of a thickness of the first metal layer and a thickness of the third metal layer.

8. The organic light-emitting display device of claim 1, wherein each of the at least metal layers includes Ag or an Ag alloy.

9. The organic light-emitting display device of claim 8, wherein the Ag alloy contains Ag and at least one of Yb, Mg, Cu, Al, Au and Pb.

10. The organic light-emitting display device of claim 1, wherein the dielectric layer includes an oxide including at least one of SiNₓ, SiOₓ, AlOₓ, IZO, ZnO and ITO, an organic material including at least one of a monomer, a polymer and polyimide (PI), or a combination of the oxide and the organic material.

11. The organic light-emitting display device of claim 1, wherein an encapsulation layer is further disposed between the color purifier layer and the light-emitting element or between the color purifier layer and the color filter layer.

12. The organic light-emitting display device of claim 1, wherein:
an encapsulation layer is further disposed between the light-emitting element and the color filter layer; and
the color purifier layer is disposed in the encapsulation layer.

13. The organic light-emitting display device of claim 12, wherein the encapsulation layer includes an ultraviolet hardening sealant or a frit sealant.

14. The organic light-emitting display device of claim 1, wherein the at least two metal layers do not include a hole overlapping the color filter layer.

15. The organic light-emitting display device of claim 1, wherein the at least one dielectric layer has a first thickness at a first portion overlapping the light-emitting element and a second thickness at a second portion overlapping a contact area between adjacent color filters of the color filter layer.

16. The organic light-emitting display device of claim 1, wherein the color purifier layer is disposed in contact with the light-emitting element and the color filter layer.

17. The organic light-emitting display device of claim 1, wherein the light-emitting element emits white light.

18. The organic light-emitting display device of claim 17, wherein the color purifier layer is configured to amplify and preferentially transmit the white light from the light-emitting element in specific wavelength ranges of about 400 nm to 480 nm, about 470 nm to 570 nm and about 660 nm to 700 nm.

19. The organic light-emitting display device of claim 18, wherein transmission peaks of the white light is at about 450 nm, about 530 nm, and about 640 nm.

20. An organic light-emitting display device comprising:
a plurality of pixels on a substrate, each pixel including a plurality of sub-pixels;
a light-emitting element formed in each of the plurality of sub-pixels, and configured to emit white light;
a color filter layer including a plurality of color filters located on the light-emitting elements to correspond to one of the plurality of sub-pixels; and
a color purifier layer located between the light-emitting element and the color filter layer and configured to amplify and preferentially transmit the white light from the light-emitting element at transmission peaks of about 450 nm, about 530 nm, and about 640 nm.
